(19) United States
(12) Patent Application Publication
(10) Pub. No.: US 2009/0057795 A1
(43) Pub. Date: Mar. 5, 2009

(54) Sensor chip having conductivity film

(75) Inventor: Seiichiro Ishio, Kariya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/230,262

(22) Filed: Aug. 26, 2008

(30) Foreign Application Priority Data
Aug. 29, 2007 (JP) 2007-223161

(51) Int. Cl. G01R 33/02; H01L 29/82

(52) U.S. Cl. 257/423; 324/252; 257/E29.323

(57) ABSTRACT

A sensor chip is provided that includes a sensor element and a control circuit for controlling the sensor element disposed in semiconductor substrate. The control circuit includes a plurality of circuit elements, each of which is isolated by P-N junction separation. The sensor chip further includes a conductivity film disposed on and surrounding at least one of the circuit elements, and having an electric potential fixed to a predetermined value.

### CROSS REFERENCE TO RELATED APPLICATIONS

The present application is based on and claims priority to Japanese Patent Application No. 2007-223161 filed on Aug. 29 2007, the disclosure of which is incorporated herein by reference.

### BACKGROUND OF THE INVENTION

1. Field of the Invention

The present invention relates to a sensor chip and, more particularly to a sensor chip having a sensor element and a control circuit both of which are formed in a same semiconductor substrate.

2. Description of Related Art

Japanese Patent Application Publication Number 2004-264205, corresponding to U.S. Pat. No. 7,250,760, recites a sensor chip including a sensor element and a control circuit for controlling the sensor element. The sensor element and the control circuit are formed in a same semiconductor substrate.

FIG. 8 is a cross sectional diagram illustrating one example of a magnetic sensor chip 90 disclosed in Japanese Patent Application Publication Number 2004-264205. In FIG. 8, a magneto-resistance element (MRE) forming region 91 and a processing circuit forming region 92 are located in single chip. The processing circuit forming region 92 provides a bipolar-transistor.

As shown in FIG. 8, the processing circuit forming region 92 of the senor chip 90 includes an N+ type buried layer 40 and an N− type epitaxial layer 41 both of which are formed in a principal surface of a P type semiconductor substrate 9 made of silicon. A silicon oxidation film 42 is formed on a principal surface of the N− type epitaxial layer 41 by chemical vapor deposition (CVD). A predetermined circuit pattern is printed on the silicon oxidation film 42 by photo-etching. Through an opening provided by the photo-etching, a P+ type element separation region 43, a P+ type diffusion region 44 and N+ type diffusion regions 45, 46 are formed by diffusing impurities. Diffusion in the above described manner provides the sensor chip 90 with an NPN bipolar transistor element having the N+ type buried layer 40, the N− type epitaxial layer 41, the P+ type diffusion region 44, and the N+ type diffusion region 45, 46.

In the MRE forming region 91, a contact element is formed in the silicon oxidation film 42. An aluminum line element 47 having a film shape is formed on the principal surface of the P type semiconductor substrate 9. The aluminum line element 47 is formed by vapor deposition and is patterned by photo-etching. A ferromagnetic film 48 is formed above the silicon oxidation film 42 and the aluminum line element 47 by vacuum deposition. The ferromagnetic film 48 is made of Ni—Co alloy or Ni—FE alloy, and functions as an MRE. An electric circuit is provided by electrical connection between circuit elements such as the NPN transistor, a PNP transistor (not shown), a diffusion resistor or a capacitor through the aluminum line element 47.

The sensor chip 90 shown in FIG. 8 may be placed adjacent to a rotator, and may measure a change in bias magnetic field according to rotation of the rotator. The sensor chip 90 can detects a rotational state of the rotator such as a rotation angle, angular velocity, or the like. The sensor chip 90 can be installed into a magnetic sensor. Such a magnetic sensor can be employed as a rotation sensor for use in controlling an engine of a vehicle or for use in controlling an Anti-Lock Brake system (ABS).

An insulation protection film 49 is formed on a surface of the sensor chip 90. When the sensor chip 90 is placed adjacent to a rotator, the sensor chip 90 can easily become electrically charged due to external static electricity. For example, when the sensor chip 90 having the NPN bipolar transistor element is electrically charged, a channel is formed between the P+ type element separation region 43 and the P+ type diffusion region 44. Accordingly, a parasitic transistor may operate and generate a leak current. An output from the NPN bipolar transistor element of the sensor chip 90 may easily fluctuate.

### SUMMARY OF THE INVENTION

In view of the above described and other difficulties, it is an objective of the present invention to provide a sensor chip that restricts an abnormal characteristic and an increase in manufacturing cost.

According to a first aspect of the present invention, a sensor chip is provided that includes a sensor element and a control circuit formed in a same semiconductor substrate. The control circuit is configured to control the sensor element. The control circuit includes multiple circuit elements spaced away from each other by P-N junction isolation. The sensor chip further includes a conductivity film disposed over and surrounding at least one of the multiple circuit elements. The conductivity film is capable of having an electric potential fixed to a predetermined value.

According to the above sensor chip, the multiple circuit elements are spaced away from each other by P-N junction isolation and the conductivity film is located over and surrounds the multiple circuit elements. The electrical potential of the conductivity film is fixed to the predetermined value when, for example, the sensor chip is energized. When the sensor chip is placed in an environment where parts can easily become electrically charged, parts around the circuit element surrounded by the conductivity film are resistant to becoming electrically charged due to the electrical potential of the conductivity film. Even when the parts are electrically charged, the electrical potential of the conductivity film restricts an influence of stored charges on the circuit element surrounded by the conductivity film. The electrical potential of the conductivity film restricts an abnormal characteristic in the circuit element.

According to a second aspect of the present invention, a magnetic sensor chip is provided. The magnetic sensor includes a semiconductor substrate having a principal surface. The magnetic sensor further includes a magneto-resistance element for sensing a magnetic field. The magneto-resistance element is formed in a surface portion of the principal surface of the semiconductor substrate. The magnetic sensor further includes a control circuit for controlling the magneto-resistance element. The control circuit is formed in another surface portion of the principal surface of the semiconductor substrate. The control circuit and the magneto-resistance element are spaced away from each other by PN junction isolation. The control circuit includes multiple circuit elements spaced away from each other by PN junction isolation. The magnetic sensor further includes multiple insulating layers respectively disposed on the plurality of circuit elements. The magnetic sensor further includes multiple conductivity film respectively disposed on the plurality of insulating layer so that the plurality of insulating layer respectively located between the plurality of conductivity film and the plurality of circuit elements. Each conductivity film has an electric potential grater than or equal to the electric potential of the corresponding circuit element when the control circuit is energized. The electric potential of each conductivity film restricts an operation of a parasitic element in the control circuit when an electric filed resulting from external static electricity is applied to the control circuit. The magneto-resistance element and the plurality of conductivity films are made of a same material and formed at a same time.

According to the above magnetic sensor chip, each of the multiple conductivity films are located over and surround respective ones of the multiple circuit elements. The electrical potential of each conductivity film is fixed to the predetermined value when, for example, the magnetic sensor chip is energized. When the magnetic sensor chip is placed in an environment where parts can easily become electrically charged, the electrical potential of the conductivity film effectively prevent parts in the control circuit from being electrically charged. Even when the parts are electrically charged, the electrical potentials of the conductivity films restrict an influence of stored charges on the control circuit. The electrical potential restricts an abnormal characteristic in the circuit element such as an operation of a parasitic element. Since the magneto-resistance element and the plurality of conductivity films are made of a same material and formed at a same time, it is possible to suppress an increase in manufacturing cost.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional diagram illustrating a sensor chip in accordance with exemplary embodiments;

FIG. 2A is a cross sectional diagram illustrating a rotation sensor and a rotator in accordance with exemplary embodiments;

FIG. 2B is a layout diagram illustrating an arrangement of the rotation sensor and the rotator in accordance with exemplary embodiments;

FIG. 3 is a cross section diagram illustrating an effect of a conductivity film on a sensor chip illustrated in FIG. 1;

FIG. 4A is a layout diagram illustrating elements of a control circuit including bipolar transistor elements in accordance with a first modification of exemplary embodiments;

FIG. 4B is a cross sectional diagram illustrating a cross sectional view taken along line IVB-IVB in FIG. 4A;

FIG. 5A is a layout diagram illustrating elements of a control circuit including bipolar transistor elements in accordance with a second modification of exemplary embodiments;

FIG. 5B is a cross sectional diagram illustrating a cross sectional view taken along line VB-VB in FIG. 5A;

FIG. 6A is a layout diagram illustrating elements of a control circuit including bipolar transistor elements in accordance with a third modification of the exemplary embodiments;

FIG. 6B is a cross sectional diagram illustrating a cross sectional view taken along line VIB-VIB in FIG. 6A;

FIG. 7A is a layout diagram illustrating elements of a control circuit including bipolar transistor elements in accordance with a fourth modification of exemplary embodiments;

FIG. 7B is a cross sectional diagram illustrating a cross sectional view taken along line VIIB-VIIB in FIG. 7A;

FIG. 8 is a cross sectional diagram illustrating a sensor chip in accordance with the related art.

FIG. 9 is a cross sectional diagram illustrating an influence of electrical charging on a sensor chip in accordance with exemplary embodiments.

### DETAILED DESCRIPTION OF THE EXEMPLARY EMBODIMENTS

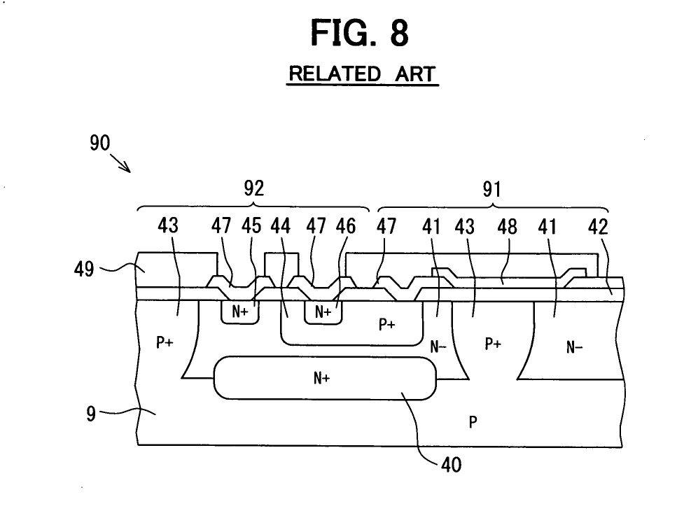

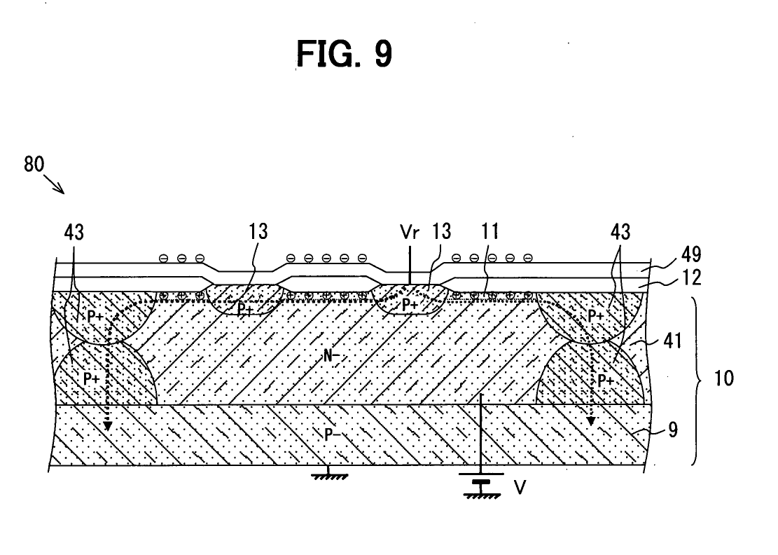

An influence of the electrical charging on a sensor chip is described below with reference to FIG. 9. Like reference numerals refer to like parts in FIG. 9 and FIG. 8.

As shown in FIG. 9, the semiconductor chip 80 includes a semiconductor substrate 10 having an N conductivity type layer 41, such as an N− conductivity type. PN-junction isolation separates the N conductivity type layer 41 to form a resistance element forming region. Resistance elements each having a P conductivity type diffusion region 13, such as a P+ conductivity type, are formed. A local oxidation of silicon (LOCOS) oxidation film 12 is located between the resistance elements. The insulation protection film 49 is formed on an utmost surface of the semiconductor chip 80. When electrical charges are stored in the insulation protection film 49 due to static electricity, a channel 11 is induced in a surface portion of the N conductivity type layer 41 by the stored charges. The formation of the channel 11 causes the parasitic transistor to operate. The formation of the channel 11 also causes the leak current to flow between the P+ element separation regions 43 grounded.

The above effect of the electrical charging may be restricted by shielding the sensor chip in such a manner that a conductive film is buried in a package receiving the sensor chip. However, the shielding of the sensor chip by using the package requires a special configuration for fixing an electric potential of the conductive film buried in the package. The configuration of the package may become complex and the manufacturing cost may increase. Moreover, another part may have a parasitic capacitance, and as a result, tolerance for noise may not increase. In view of the above and other difficulties, a sensor chip is described below that can restrict an abnormal characteristic and an increase in manufacturing cost.

### Exemplary Embodiments

A sensor chip according to exemplary embodiments is described below with reference to the accompanying drawings.

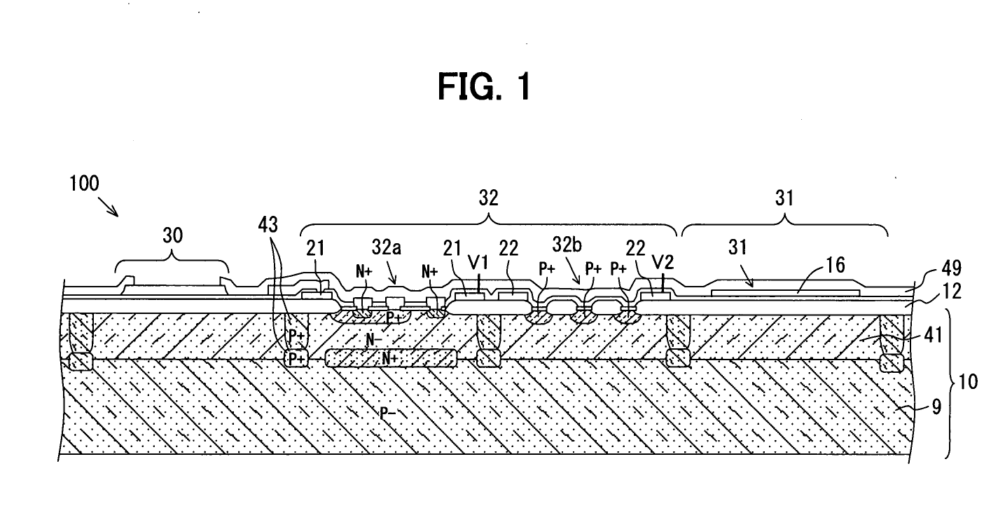

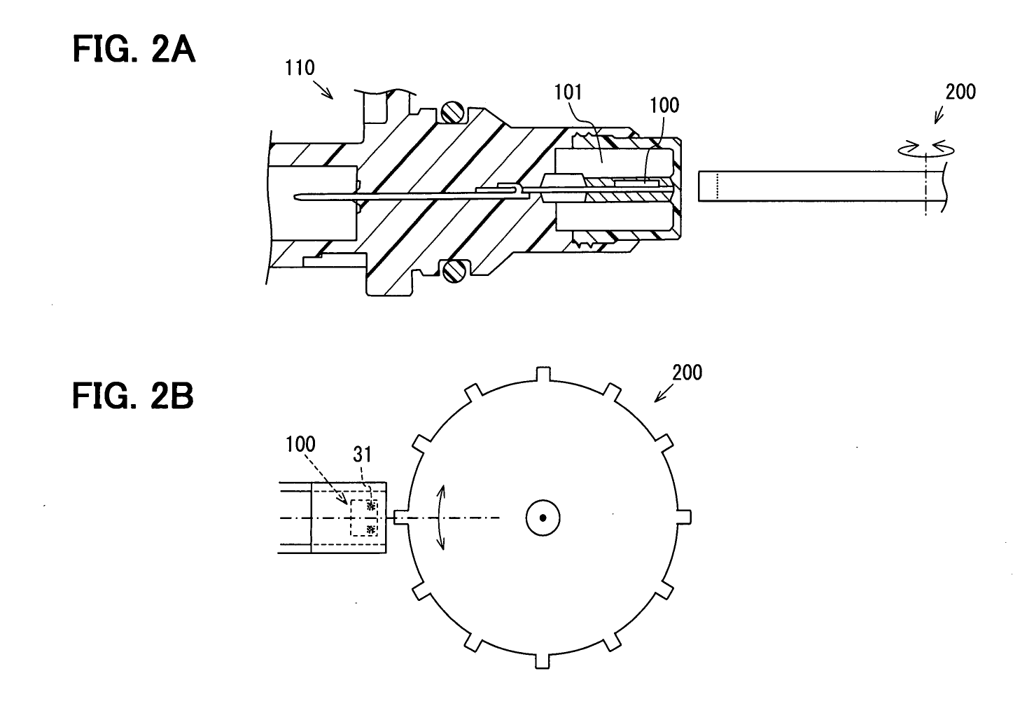

A sensor chip 100 illustrated in FIG. 1 is a magnetic sensor chip used as an element of a rotation sensor. As shown in FIG. 2A and FIG. 2B, the sensor chip 100 is placed adjacent to a rotator that is connected with a cam or a crank. The sensor chip 100 can measure the change in bias magnetic field that accompanies rotation of the rotator 200.

As shown in FIG. 1, the sensor chip 100 includes a semiconductor substrate 10, a pad portion 30, a sensor element 31, a control circuit 32 for controlling the sensor element 31, and an insulating layer 12. The sensor element 31 and the control circuit 32 are formed in the same semiconductor substrate 10. The sensor element 31 may be a magneto-resistance element 31. The insulating layer 12 may be a LOCOS oxidation film 12.

The sensor element 31 includes a ferromagnetic film 16 made of Ni—Co alloy, Ni—FE alloy or the like.

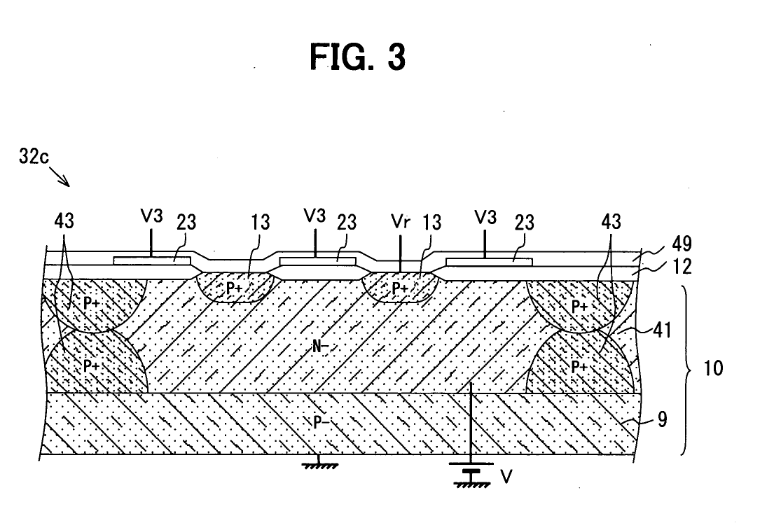

The control circuit 32 includes multiple circuit elements spaced away from each other by PN junction isolation. The PN junction isolation is provided by P+ type element separation regions 43. In FIG. 1, a bipolar transistor element 32a and a resistance element 32b are illustrated as examples of the multiple circuit elements in the control circuit 32. A conductive film 21 is formed over the bipolar transistor element 32a so as to surround the bipolar transistor element 32a. An electrical potential of the conductive film 21 is fixed to a predetermined value V1 when, for example, the sensor chip 100 is energized. Another conductive film 22 is formed over the resistance element 32b so as to surround the resistance element 32b. An electrical potential of the conductive film 22 is fixed to a predetermined value V2 when the sensor chip 100 is energized for instance. As shown in FIG. 3, a conductive film 23 is formed over a resistance element 32c so as to surround the resistance element 32c. An electrical potential of the conductive film 23 is fixed to a predetermined value V3 when the sensor chip 100 is energized for instance.

As described above, as shown in FIG. 1 and FIG. 3, the sensor chip 100 includes the control circuit 32 having the multiple circuit elements 32a to 32c isolated by PN junction isolation. The conductivity film 21 to 23 is located over each circuit element 32a to 32c and surrounds the circuit element 32a to 32c. Electric potentials of the conductivity films 21, 22, 23 can be fixed to predetermined values V1, V2, V3, respectively. Even when the sensor chip 100 is placed in an environment where an element can easily become electrically charged, the conductivity films 21, 22, 23 having the electrical potentials V1, V2, V3 cause parts around the circuit elements 32a, 32b, 32c to be resistant to be electrically charged. Even when parts are electrically charged, the electrical potentials V1, V2, V3 of the conductivity films 21, 22, 23 restrict influence of the electrostatic charge on the circuit elements 32a to 32c surrounded by the conductivity films 21 to 23. It is possible to restrict an abnormal characteristic of the circuit elements 32a to 32c. For example, the resistance element 32c illustrated in FIG. 3 is more difficult to have a leakage current compared to the resistance element illustrated in FIG. 9. In the resistance element 32c illustrated in FIG. 3, a parasitic transistor is more difficult to operate compared to a case in the resistance element illustrated in FIG. 9.

In the sensor chip 100, the conductivity film 21 to 23 is disposed over all circuit elements 32a to 32c illustrated in FIG. 1 and FIG. 3. Alternatively, the conductivity film may be disposed over at least one circuit element that relatively easily becomes electrically charged. Alternatively, the conductivity film may be disposed on at least one circuit element which can be considerably influenced by the electrostatic charges.

Alternatively, the sensor chip may have the following configuration. The conductivity films may be disposed over more then one circuit element of the multiple circuit elements of the control circuit 32. The conductivity films may be spaced away from each other. Electric potentials of the conductivity films may be different from each other. In the above case, regarding each circuit element, it is possible to appropriately set the electrical potential to be applied to each conductivity film and to efficiently prevent the circuit element from being electrically charged and having an abnormal characteristic. When the electrical potential of the conductivity film for each circuit element is individually set, the electric potential of the conductivity film may be maximum among parts of the above-described circuit element.

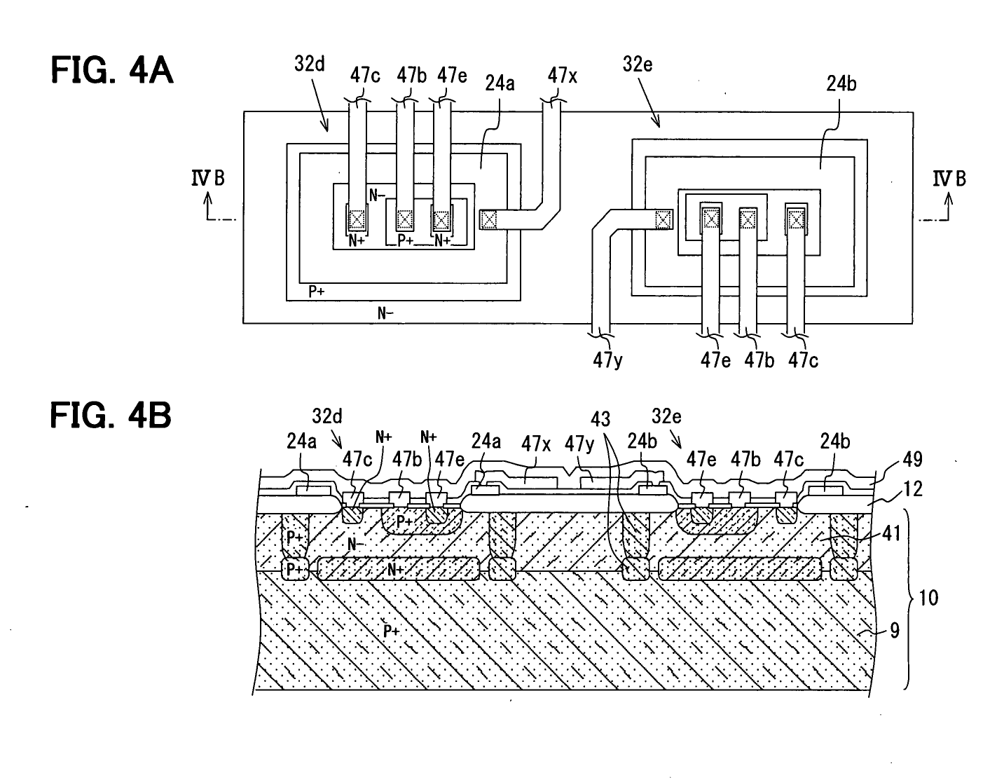

Modifications according to the exemplary embodiments are described below with reference to FIG. 4 to FIG. 7. Like reference numerals refer to like parts in FIGS. 1 and 4 to FIG. 7.

(First Modification)

A first modification is described below with reference to FIG. 4A and FIG. 4B. Each conductivity film 24a, 24b has a substantially ring shape so that the conductivity films 24a, 24b respectively surround peripheries of bipolar transistor elements 32d, 32e. The conductivity films 24a, 24b are connected with wire elements 47x, 47y, respectively. The wire elements 47x, 47y are provided differently from the wire elements 47e, 47b, 47c. The wire elements 47e, 47b, 47c are connected with each bipolar transistor element 32d, 32e. Electric potentials of the conductivity films 24a, 24b can be fixed to predetermined values, respectively.

(Second Modification)

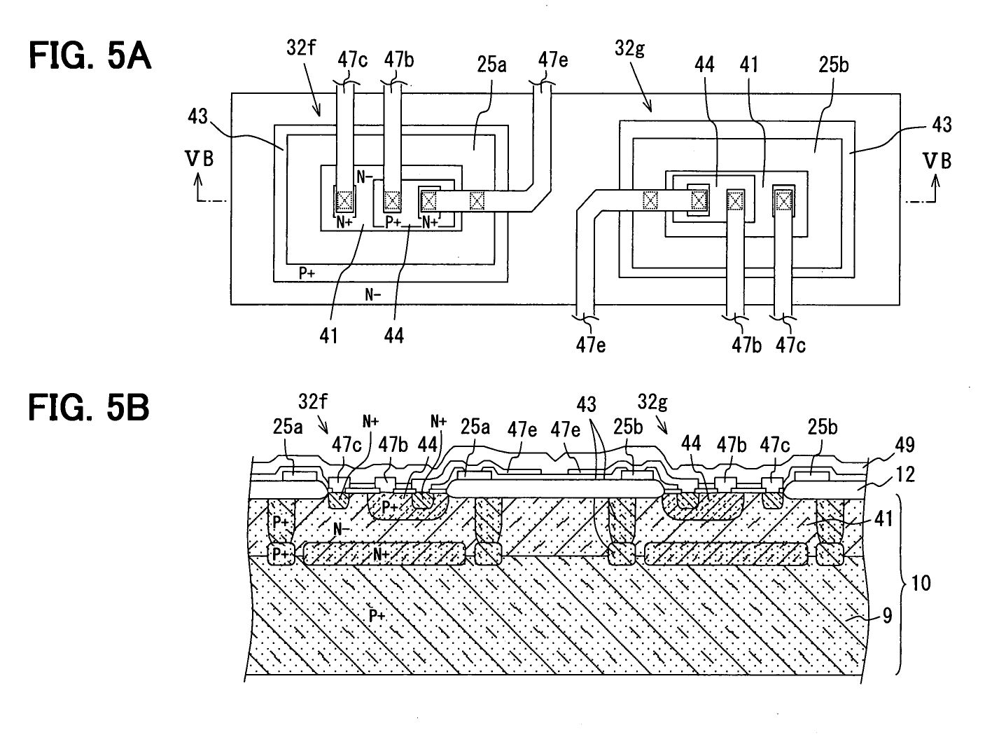

A second modification is described below with reference to FIG. 5A and FIG. 5B. Each conductivity film 25a, 25b has a substantially ring shape so that the conductivity films 25a, 25b respectively surround peripheries of bipolar transistor elements 32f, 32g. The conductivity films 25a, 25b are, respectively, connected with emitter connection lines 47e. The emitter connection lines 47e are, respectively, connected with the bipolar transistor elements 32f, 32g. Electrical potentials of the conductivity films 25a, 25b can be fixed to those of the emitters of the bipolar transistor elements 32f, 32g, respectively.

(Third Modification)

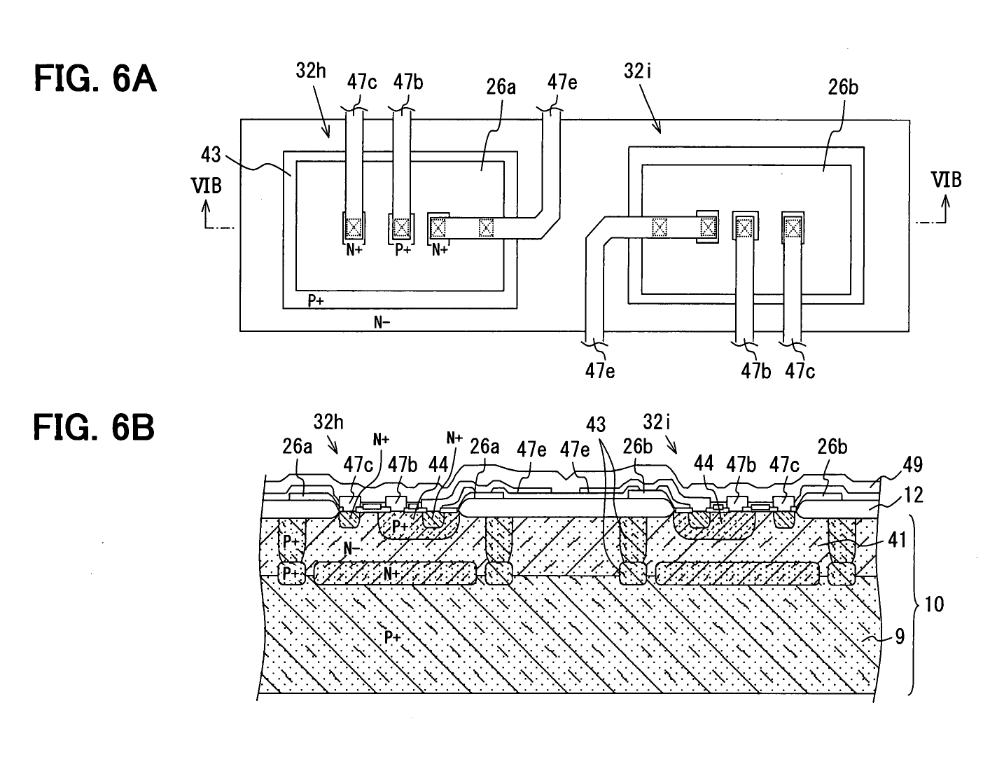

A third modification is described below with reference to FIG. 6A and FIG. 6B. Conductivity films 26a, 26b are located respectively over transistor elements 32h, 32i, and surround the bipolar transistor elements 32h, 32i. Each of the conductivity films 26a, 26b have a respective connection with the emitter line elements 47e. Electrical potentials of each of the conductivity films 26a, 26b can be fixed respectively to those of the emitters of the bipolar transistor elements 32h, 32i. When comparison is made between FIG. 5A and FIG. 6A, each conductive film 26a, 26b illustrated in the FIG. 6A and FIG. 6B covers substantially whole surface of the bipolar transistor element 32h, 32i whereas each conductive film 25a, 24b illustrated in FIG. 5A and FIG. 6A partially covers the surface of the bipolar transistor element 32g, 32h.

In the sensor chip 100 illustrated in FIG. 1, the sensor element includes a first conductivity type region and a second conductivity type region in a surface portion of the semiconductor substrate. In the above configuration, the conductive film covers the first conductivity type region between the second conductivity type regions. For example, in each bipolar transistor element 32f, 32g, a portion corresponding the N conductivity type region 41 positioned between the P type regions 43, 44 may potentially operate as a parasitic PNP transistor due to electrostatic charges. The parasitic PNP transistor may potentially cause leakage current. In view of the above described action of the potential parasitic element, the conductive film 26a, 26b is located so as to cover the portion that potentially functions as the parasitic PNP transistor in each bipolar transistor element 32h, 32i illustrated in FIG. 6A and FIG. 6B. The above configuration more efficiently restricts the influence of the electrostatic charges on each bipolar transistor element 32h, 32i surrounded by the conductivity film 26a, 26b. It is therefore possible to effectively prevent the bipolar transistor elements 32h, 32i from having an abnormal characteristic.

(Fourth Modification)

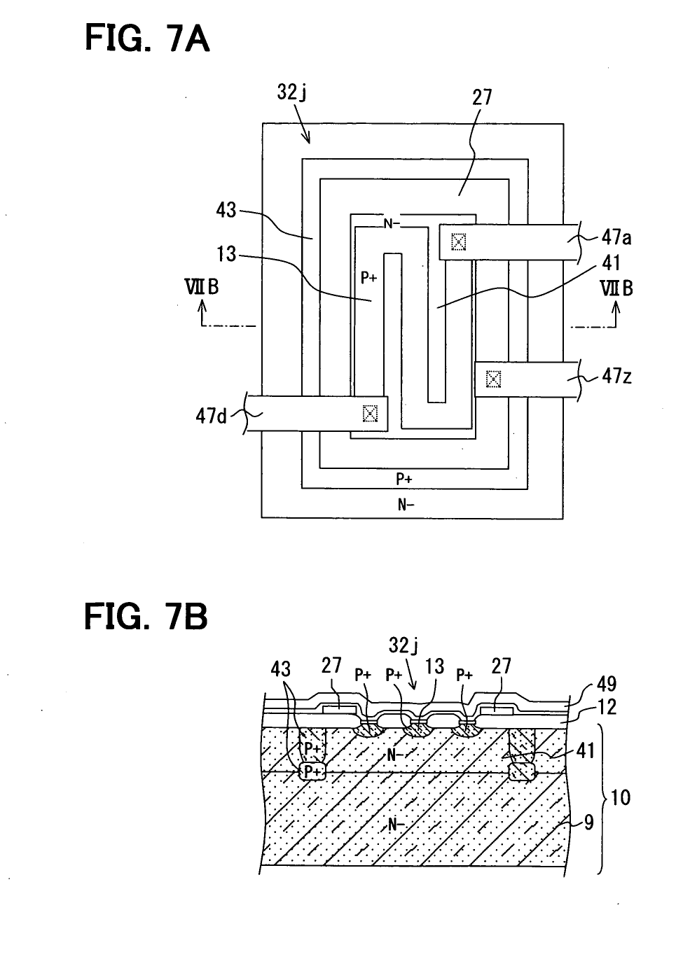

A fourth modification is described below with reference to FIG. 7A and FIG. 7B. A conductivity film 27 is located so as to surround a resistance element 32j. The conductivity film 27 is connected with a line element 47z. The line element 47z is different from line elements 47a, 47d connected with the resistance element 32j. An electric potential of the conductivity film 27 can be fixed to a predetermined value. The conductivity film 27 covers the N conductivity type region 41 located between the P type regions 43, 13, as shown in FIG. 7A and FIG. 7B.

In the above exemplary embodiments and modifications, a layer of each conductivity film 21 to 23, 24a to 26a, 27 is different from that of the line element 47a to 47e. Accordingly, it is possible to restrict short-circuiting between the conductivity film 21 to 23, 24a to 26a, 27 and the line element 47a to 47e. Forming the above conductivity film 21 to 23, 24a to 26a, 27 can be performed by known semiconductor processing. Thus, it is possible to suppress an increase in manufacturing cost. The conductivity films 21 to 23, 24a to 26a, 24b to 26b, 27 is made of electrically-conductive material such as polycrystalline silicon, titanium-tungsten alloy, aluminum, or the like. The above materials are widely used in manufacturing a semiconductor device. The use of the above materials can suppress an increase in manufacturing cost.

The conductivity films 21 to 23, 24a to 26a, 24b to 26b, 27 and the ferromagnetic film 16 may be made of the same material and may be formed at the same time. According to the above manners, processes for manufacturing the ferromagnetic film 31 and the conductivity films 21 to 23, 24a to 26a, 24b to 26b, 27 are designed to a common process. Thereby, it is possible to suppress an increase in manufacturing cost.

As described above, according to the above embodiments and modifications, the sensor chip includes the sensor element and the control circuit for the sensor element formed in the same semiconductor substrate. The sensor chip is configured such that the conductivity film protects the circuit element from the influence of electric charging due to, for example, static electricity. The sensor chip can be manufactured at a low cost.

In view of the above, the sensor chip according to the above embodiments and modifications can be suitable for use in an environment where parts easily become electrically charged. As illustrated in FIG. 1 and FIG. 2, the sensor chip may be used as a magnetic sensor chip placed adjacent to a rotator and used for measuring a change in magnetic field resulting from rotation of the rotator. The sensor element may be used as a magnetic sensor element for sensing the magnetic field. The sensor chip may be suitable for use in a vehicle where the environment is harsh in terms of electrical charging and where low cost manufacturing may be required.

The disclosure described herein has the following aspects.

According to a first aspect of the disclosure, a sensor chip is provided that includes a semiconductor substrate 10, a sensor element 31 formed in the semiconductor substrate 10, and a control circuit 32 for controlling the sensor element 31. The control circuit 32 and the sensor element 31 are formed in the same semiconductor substrate 10. The control circuit 32 has multiple circuit elements 32a to 32j spaced away from each other by P-N junction isolation. The sensor chip further includes a conductivity film 21 to 23, 24a to 26a, 24b, 26b, 27 disposed over and surrounding at least one of the circuit elements 32a to 32j. An electric potential of the conductivity film 21 to 23, 24a to 26a, 24b, 26b, 27 is fixed to a predetermined value.

According to the above sensor chip, the multiple circuit elements 32a to 32j are spaced away from each other by P-N junction isolation and the conductivity film 21 to 23, 24a to 26a, 24b, 26b, 27 is located over and surrounds the multiple circuit elements 32a to 32j. The electrical potential of the conductivity film is fixed to the predetermined value when, for example, the sensor chip is energized. When the sensor chip is placed in an environment where parts can easily become electrically charged, parts around the circuit element surrounded by the conductivity film 21 to 23, 24a to 26a, 24b, 26b, 27 are resistant to becoming electrically charged due to the electrical potential of the conductivity film 21 to 23, 24a to 26a, 24b, 26b, 27. Even when the parts are electrically charged, the electrical potential of the conductivity film 21 to 23, 24a to 26a, 24b, 26b, 27 restricts an influence of stored charges on the circuit element surrounded by the conductivity film 21 to 23, 24a to 26a, 24b, 26b, 27. The electrical potential of the conductivity film 21 to 23, 24a to 26a, 24b, 26b, 27 restricts an abnormal characteristic in the circuit element 32a to 32j.

Alternatively, the circuit element 32a to 32j may include a first conductivity type region and a second conductivity type region. The conductivity film 21 to 23, 24a to 26a, 24b, 26b, 27 covers a portion of the first conductivity type region, the portion being located between the second conductivity type region.

Alternatively, each circuit element 32a to 32j may include one of a bipolar transistor element and a resistance element.

Alternatively, the sensor chip may further include a wiring layer 47a to 47e disposed in a first layer of the semiconductor substrate 10 and connected with the circuit elements 32a to 32j. The conductivity film 21 to 23, 24a to 26a, 24b, 26b, 27 is disposed in a second layer of the semiconductor substrate 10. The first layer is different from the second layer.

Alternatively, the conductivity film 21 to 23, 24a to 26a, 24b, 26b, 27 may be made of a material selected from the group consisting of polycrystalline silicon, titanium-tungsten, and aluminum.

Alternatively, each sensor element 31 may include a magneto-resistance element 31. Each magneto-resistance element 31 and the conductivity film 21 to 23, 24a to 26a, 24b, 26b, 27 are made of a same material and formed at a same time.

Alternatively, the same material may include one of nickel-iron alloy and nickel-cobalt alloy.

Alternatively, the conductivity film 21 to 23, 24a to 26a, 24b, 26b, 27 may have a substantially ring shape and surrounds a periphery of the at least one of the circuit elements 32a to 32j.

Alternatively, the conductivity film 21 to 23, 24a to 26a, 24b, 26b, 27 may substantially cover a whole surface of the at least one of the circuit elements 32a to 32j.

Alternatively, the conductivity film 21 to 23, 24a to 26a, 24b, 26b, 27 may include a first-film part 21 to 23, 24a to 26a, 24b, 26b, 27 and a second film part 21 to 23, 24a to 26a, 24b, 26b, 27 spaced away from each other. The plurality of circuit elements 32a to 32j includes a first circuit element and a second circuit element. The first film part 21 to 23, 24a to 26a, 24b, 26b, 27 is disposed over the first circuit element 32a to 32j. The second film part 21 to 23, 24a to 26a, 24b, 26b, 27 is disposed over the second circuit element 32a to 32j. An electric potential of the first film part 21 to 23, 24a to 26a, 24b, 26b, 27 is fixed to a first predetermined value. An electric potential of the second film part 21 to 23, 24a to 26a, 24b, 26b, 27 is fixed to a second predetermined value.

Alternatively, the electric potential applied to the conductivity film 21 to 23, 24a to 26a, 24b, 26b, 27 may be greater than or equal to that applied to the at least one of the circuit elements 32a to 32j.

Alternatively, the sensor chip may be located adjacent to a rotator and may be used for measuring a change in magnetic filed, the change being caused by rotation of the rotator. The sensor element 31 includes a magnetic sensor element 31 for sensing the magnetic field.

Alternatively, the sensor chip may be mounted to a vehicle.

Alternatively, the conductivity film 21 to 23, 24a to 26a, 24b, 26b, 27 may include multiple film parts, each of which is disposed over each circuit element 32a to 32j. The conductivity film 21 to 23, 24a to 26a, 24b, 26b, 27 restricts generation of a parasitic element and a leakage current in the control circuit, the generation being caused by external static electricity.

According to a second aspect of the disclosure, a magnetic sensor chip is provided that includes: a semiconductor substrate 10 having a principal surface; a magneto-resistance element 31 for sensing a magnetic field, the magneto-resistance element 31 being formed in a surface portion of the principal surface of the semiconductor substrate 10; a control circuit 32 for controlling the magneto-resistance element 31, the control circuit 32 being formed in another surface portion of the principal surface of the semiconductor substrate 10, the control circuit 32 and the magneto-resistance element 31 being spaced away from each other by PN junction isolation, the control circuit 32 including multiple circuit elements 32a to 32j spaced away from each other by PN junction isolation; multiple insulating layers 12 respectively disposed on the multiple circuit elements 32a to 32j; and multiple conductivity films 21 to 23, 24a to 26a, 24b, 26b, 27 each of which are disposed respectively on ones of the multiple insulating layers 12 so that each of the multiple insulating layers 12 are located respectively between each of the multiple conductivity film 21 to 23, 24a to 26a, 24b, 26b, 27 and each of the multiple circuit elements 32a to 32j. An electric potential of each conductivity film 21 to 23, 24a to 26a, 24b, 26b, 27 is greater than or equal to that of the corresponding circuit element when the control circuit 32 is energized. The electric potential of each conductivity film 21 to 23, 24a to 26a, 24b, 26b, 27 restricts an operation of a parasitic element in the control circuit 32 when an electric filed resulting from external static electricity is applied to the control circuit 32. The magneto-resistance element 31 and the multiple conductivity films 21 to 23, 24a to 26a, 24b, 26b, 27 are made of a same material and formed at a same time.

According to the above magnetic sensor chip, each of the multiple conductivity films 21 to 23, 24a to 26a, 24b, 26b, 27 are located over and surround respective ones of the multiple circuit elements 32a to 32j. The electrical potential of each conductivity film 21 to 23, 24a to 26a, 24b, 26b, 27 is fixed to the predetermined value when, for example, the magnetic sensor chip is energized. When the magnetic sensor chip is placed in an environment where parts can easily become electrically charged, the electrical potential of the conductivity film 21 to 23, 24a to 26a, 24b, 26b, 27 effectively prevent parts in the control circuit from being electrically charged. Even when the parts are electrically charged, the electrical potentials of the conductivity films 21 to 23, 24a to 26a, 24b, 26b, 27 restrict an influence of stored charges on the control circuit 32. The electrical potential restricts an abnormal characteristic in the circuit element 32a to 32j such as an operation of a parasitic element. Since the magneto-resistance element 31 and the multiple conductivity films 21 to 23, 24a to 26a, 24b, 26b, 27 are made of a same material and formed at a same time, it is possible to suppress an increase in manufacturing cost.

While the invention has been described above with reference to various embodiments thereof, it is to be understood that the invention is not limited to the above described embodiments and construction. The invention is intended to cover various modification and equivalent arrangements. In addition, while the various combinations and configurations described above are contemplated as embodying the invention, other combinations and configurations, including more, less or only a single element, are also contemplated as being within the scope of embodiment.

What is claimed is:

1. A sensor chip comprising:
a semiconductor substrate;
a sensor element formed in the semiconductor substrate;
a control circuit for controlling the sensor element, the control circuit and the sensor element being formed in the same semiconductor substrate, the control circuit including a plurality of circuit elements spaced away from each other by P-N junction isolation; and
a conductivity film disposed over and surrounding at least one of the circuit elements, an electric potential of the conductivity film being fixed to a predetermined value.

2. The sensor chip according to claim 1, wherein:
the circuit element includes a first conductivity type region and a second conductivity type region; and
the conductivity film covers a portion of the first conductivity type region, the portion being located between the second conductivity type region.

3. The sensor chip according to claim 1, wherein
each circuit element includes one of a bipolar transistor element and a resistance element.

4. The sensor chip according to claim 1, further comprising:
a wiring layer disposed in a first layer of the semiconductor substrate and connected with the circuit elements, wherein:
the conductivity film is disposed in a second layer of the semiconductor substrate; and
the first layer is different from the second layer.

5. The sensor chip according to claim 1, wherein
the conductivity film is made of a material selected from the group consisting of polycrystalline silicon, titanium-tungsten, and aluminum.

6. The sensor chip according to claim 1, wherein
each sensor element includes a magneto-resistance element; and
each magneto-resistance element and the conductivity film are made of a same material and formed at a same time.

7. The sensor chip according to claim 6, wherein
the same material includes one of nickel-iron alloy and nickel-cobalt alloy.

8. The sensor chip according to claim 1, wherein
the conductivity film has a substantially ring shape and surrounds a periphery of the at least one of the circuit elements.

9. The sensor chip according to claim 1, wherein
the conductivity film substantially covers a whole surface of the at least one of the circuit elements.

10. The sensor chip according to claim 8, wherein:
the conductivity film includes a first film part and a second film part spaced away from each other;
the plurality of circuit elements includes a first circuit element and a second circuit element;
the first film part is disposed over the first circuit element;
the second film part is disposed over the second circuit element;
an electric potential of the first film part is fixed to a first predetermined value; and
an electric potential of the second film part is fixed to a second predetermined value.

11. The sensor chip according to claim 8, wherein
the electric potential applied to the conductivity film is greater than or equal to that applied to the at least one of the circuit elements.

12. The sensor chip according to claim 1, wherein the sensor chip is located adjacent to a rotator and is used for measuring a change in magnetic filed, the change being caused by rotation of the rotator, wherein
the sensor element includes a magnetic sensor element for sensing the magnetic field.

13. The sensor chip according to claim 1, wherein:
the sensor chip is mounted to a vehicle.

14. The sensor chip according to claim 1, wherein:
the conductivity film includes a plurality of film parts, each of which is disposed over each circuit element; and
the conductivity film restricts generation of a parasitic element and a leakage current in the control circuit, the generation being caused by external static electricity.

15. A magnetic sensor chip comprising:
a semiconductor substrate having a principal surface;
a magneto-resistance element for sensing a magnetic field, the magneto-resistance element being formed in a surface portion of the principal surface of the semiconductor substrate;
a control circuit for controlling the magneto-resistance element, the control circuit being formed in another surface portion of the principal surface of the semiconductor substrate, the control circuit and the magneto-resistance element being spaced away from each other by PN junction isolation, the control circuit including a plurality of circuit elements spaced away from each other by PN junction isolation;
a plurality of insulating layers respectively disposed on the plurality of circuit elements; and
a plurality of conductivity films each of which are disposed respectively on ones of the plurality of insulating layers so that each of the plurality of insulating layers are located respectively between each of the plurality of conductivity film and each of the plurality of circuit elements,
wherein an electric potential of each conductivity film is greater than or equal to that of the corresponding circuit element when the control circuit is energized,
wherein the electric potential of each conductivity film restricts an operation of a parasitic element in the control circuit when an electric filed resulting from external static electricity is applied to the control circuit,
wherein the magneto-resistance element and the plurality of conductivity films are made of a same material and formed at a same time.
